(19) United States
(12) Patent Application Publication
(10) Pub. No.: US 2018/0282858 A1
(43) Pub. Date: Oct. 4, 2018

(54) CORROSION RESISTANT SPRING WITH METALLIC COATING

(71) Applicant: William M. Bailey, Humbl, TX (US)

(72) Inventor: William M. Bailey, Humbl, TX (US)

(73) Assignee: Baker Hughes Incorporated, Houston, TX (US)

(21) Appl. No.: 15/478,832

(22) Filed: Apr. 4, 2017

(51) Int. Cl. C23C 14/16; E21B 34/12; C23C 14/22

(52) U.S. Cl. CPC C23C 14/16; E21B 2034/005; C23C 14/22; E21B 34/12

(57) ABSTRACT

A spring includes a spring member including a Ni-base, Co-base or Ni—Co base alloy, the spring member having an outer surface, and a coating disposed on the outer surface of the spring member, wherein the coating includes a metal.

### BACKGROUND

### Field of the Disclosure

This disclosure relates generally to coated springs for use in wellbores.

### Background

Wellbores are drilled in subsurface formations for the production of hydrocarbons (oil and gas). Modern wells can extend to great well depths, often more than 15,000 ft. Hydrocarbons are trapped in various traps or zones in the subsurface formations at different depths. Acidizing and other techniques are used to increase the flow of fluid from the subsurface formations by the use of a quantity of a strong acid, such as concentrated hydrochloric acid, pumped downhole and into the associated rock formation. Acidizing operations can introduce corrosive fluid into the wellbore. Further, subsurface safety valves are commonly used in oil or gas wells to prevent the escape of fluids from a producing formation in the event of damage to the well conduits or to the surface elements of the well. In wellbores that utilize acidizing and other techniques, it is often desired to provide components such as subsurface safety valves that can perform a desired function while withstanding the corrosive fluids introduced by acidizing and other operations.

The disclosure herein provides a subsurface safety valve that includes a coated spring, wherein the coated spring is coated with a metallic coating.

### SUMMARY

In one aspect, a spring is disclosed that in one non-limiting embodiment contains a spring member including a Ni-base, Co-base or Ni—Co base alloy, the spring member having an outer surface, and a coating disposed on the outer surface of the spring member, wherein the coating includes a metal.

In another aspect a method of making a spring is disclosed that in one non-limiting embodiment includes forming a spring member including a Ni-base, Co-base or Ni—Co base alloy, the spring member having an outer surface, and disposing a coating on the outer surface of the spring member, wherein the coating includes a metal.

In another aspect a subsurface safety valve is disclosed that in one non-limiting embodiment includes a valve body, a flapper rotatably coupled to the valve body, and a spring configured to rotatably urge the flapper against the valve body, wherein the spring includes a spring member including an Ni-base, Co-base or Ni—Co base alloy, the spring member having an outer surface, and a coating disposed on the outer surface of the spring member, wherein the coating includes a metal.

In another aspect downhole assembly disposed in a wellbore is disclosed that in one non-limiting embodiment includes a tubing disposed in the wellbore, a subsurface safety valve associated with the tubing, the subsurface safety valve including a valve body, a flapper rotatably coupled to the valve body, and a spring configured to rotatably urge the flapper against the valve body, wherein the spring includes a spring member including an Ni-base, Co-base or Ni—Co base alloy, the spring member having an outer surface, and a coating disposed on the outer surface of the spring member, wherein the coating includes a metal.

Examples of the more important features of certain embodiments and methods have been summarized rather broadly in order that the detailed description thereof that follows may be better understood, and in order that the contributions to the art may be appreciated. There are, of course, additional features that will be described hereinafter and which will form the subject of the claims.

### BRIEF DESCRIPTION OF THE DRAWINGS

For a detailed understanding of the apparatus and methods disclosed herein, reference should be made to the accompanying drawings and the detailed description thereof, wherein like elements are generally given same numerals and wherein:

FIG. 1 shows an exemplary embodiment of a wellbore containing a subsurface safety valve, according to one non-limiting embodiment of the disclosure;

FIG. 2 shows an exemplary embodiment of a subsurface safety valve, according to one non-limiting embodiment of the disclosure suitable for use with the downhole system of FIG. 1;

FIG. 3 shows a plan view of an exemplary embodiment of a coated spring suitable for use with the subsurface safety valve shown in FIG. 2;

FIG. 4 shows an elevation view of the coated spring of FIG. 3;

FIG. 5A shows a cross sectional view of the coated spring of FIG. 3; and

FIG. 5B shows a cross sectional view of an alternative embodiment of the coated spring of FIG. 3.

### DETAILED DESCRIPTION OF THE DRAWINGS

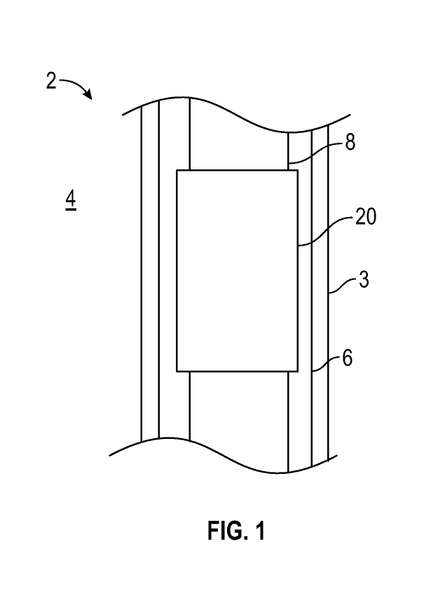

FIG. 1 is a line diagram of a section of a well completion, including the subsurface safety valve 20, used for the production of formation fluids from a well. In the illustrated embodiment, this section of the well completion 2 includes a tubing 8 disposed in a casing 6. In the illustrated embodiment, the casing 6 is installed and cemented in a wellbore 3 formed in a formation 4. In the illustrated embodiment, a subsurface safety valve 20 is attached to the tubing 8. In the illustrated embodiment, the subsurface safety valve 20 can be utilized to selectively prevent the flow of fluids from the formation 4 that flow up the tubing 8.

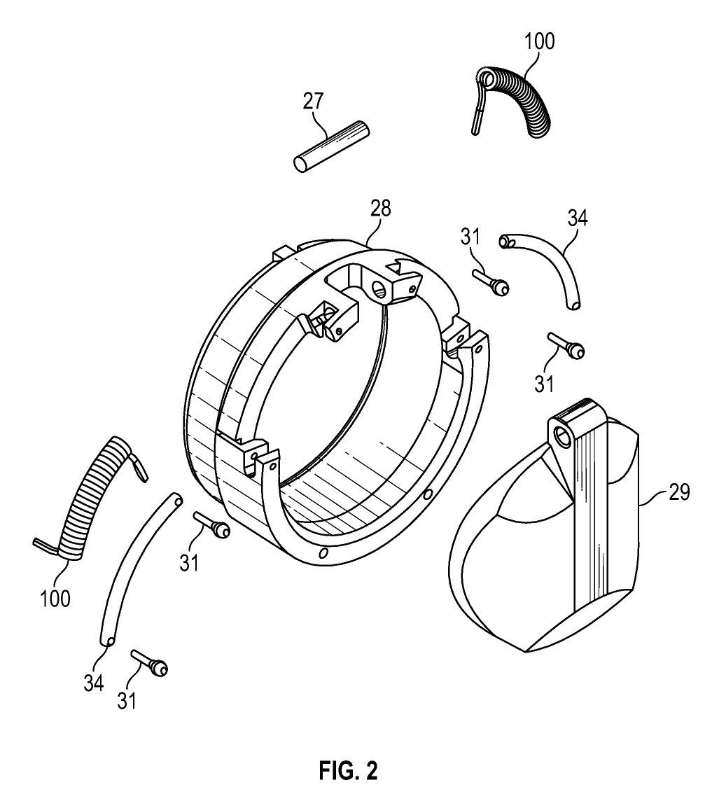

Referring to FIG. 2, an exploded assembly view of a portion of the subsurface safety valve 20 is shown. In the illustrated cross-section embodiment, the subsurface safety valve 20 includes a flapper 29, a pin 27, a housing body 28, and torsion springs 100. In the illustrated embodiment, subsurface safety valves 20 are used in oil or gas wells to prevent the escape of fluids from a producing formation in the event of damage to the well conduits or to the surface elements of the well. In certain embodiments, subsurface safety valves 20 are incorporated into the production fluid transmission tubing which is inserted through the well casing and extends from the surface of the well to the producing formation. The flow of fluids through this inner tubing string must be interrupted in the event of damage to the casing, the tubing string or to the well head. By positioning these valves at a location below the well surface, for example, below the mudline in an offshore well, the subsurface safety valve 20 can be closed to prevent the escape of produced fluids.

Referring to FIG. 2, in the illustrated embodiment, the subsurface safety valve 20 includes a hinged flapper 29, which is secured by pin 27 to the housing body 28 of the subsurface safety valve 20. In the illustrated embodiment, the torsion springs 100 are disposed around the housing body 28. In the illustrated embodiment, the pin 27 extends through the hinged flapper 29 to serve as a fixed point of rotation between the housing body 28 and the flapper 29. In certain embodiments, an alignment rod 34 can provide a desired radius to the springs 100 to match a curvature of the housing body 28. The alignment rods 34 can be disposed in the inner diameter of the springs 100. In certain embodiments, the alignment rods 34 can be fastened to the housing body 28 with alignment rod pins 31.

Continuing, in the illustrated embodiment, a first end of the torsion spring 100 is connected, affixed, or otherwise operatively coupled to the flapper 29 either directly or via the flapper pin 27. The opposite ends of the torsion springs 100 are is connected, affixed, or otherwise operatively coupled the housing body 28. In certain embodiments the torsion springs 100 are installed in a machined feature, affixed with a pin or set screw, or torsional legs are utilized to allow the torsional springs 100 to act on the housing body 28.

During operation, the torsion springs 100 allows for an internal component (i.e. flow tube) to rotationally displace the flapper 29 to the “open position” and return the flapper 29 to the “closed position” upon removal of the flow tube. During normal operation the flow tube (not shown) is actuated or “pushed down” through the subsurface safety valve 20, the torsion springs 100 inducing a torsional load (effectively winding up the springs) and rotationally biasing as the flapper 29 open through an arc to allow fluid flow through the safety valve 20.

When the flow tube is allowed to move upwardly, the springs 100 initiate the reverse and return movement of the flapper 29 until the subsurface safety valve 20 closes.

In certain applications, acidizing operations are utilized in wellbores that include the subsurface safety valve 20. Acidizing is a technique for increasing the flow of oil from a well by the use of a quantity of a strong acid, such as concentrated hydrochloric acid, pumped downhole and into the associated rock formation. In certain embodiments, the hydrochloric acid can be diluted to 15-28%. In certain applications, the acid is pumped or forced under high pressure into a limestone formation, thereby dissolving the limestone, enlarging the cavity and increasing the surface area of the hole opposite the producing formation. The high pressure of the treatment also forces the acid into cracks and fissures enlarging them and resulting in an increased flow of oil into the wellbore. After injection into the limestone formation, the acid and dissolved constituents that are heated in the formation are removed from the wellbore. Flow tube and components of the subsurface safety valve 20, including the torsion spring 100, are exposed to the hot acidizing fluid. This acidizing fluid not only contains the hot acid, but also contains oil, gases, water, and dissolved ionic constituents of the rock formation into which it is injected. The acid and other ionic species contained in the acidizing fluid make this fluid very corrosive.

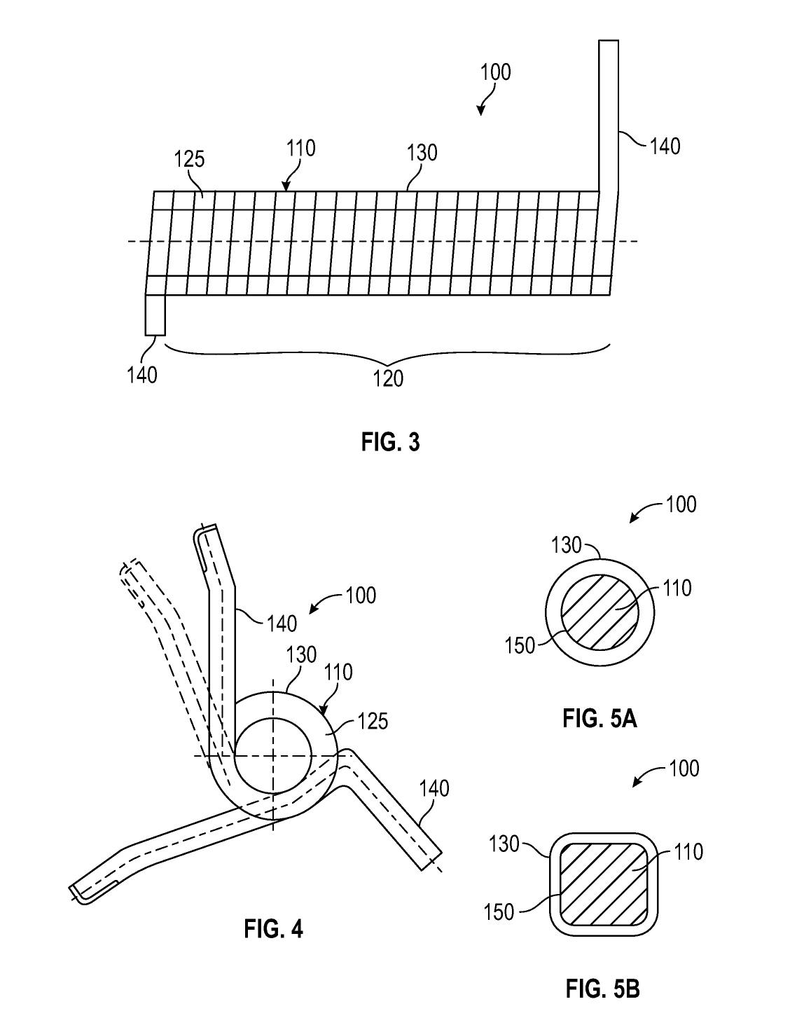

Therefore, it is desired to provide a torsion spring 100 that can withstand exposure to heat, acid, and other ionic species contained in the acidizing fluid. Referring to FIGS. 3 and 4, a torsion spring 100 suitable for use with the subsurface safety valve 20 is shown. In the illustrated embodiment, the torsion spring 100 includes a spring member 110, a coil segment 120, coils 125, a coating 130, and spring ends 140. In certain embodiments, the torsion spring 100 may include any suitable spring form, including various leaf spring, torsion bar and coil spring forms. The torsion spring 100 may particularly include various coil spring forms employed as torsion or compression springs, and more particularly as torsion springs used in various flapper valve designs, including those employed in subsurface safety valves 20 for various wellbore applications. The coil spring forms may be formed from any suitable wire having any suitable cross-sectional shape, including circular, rectangular, elliptical and arcuate shapes and the like, and these shapes may incorporate features such as radiused, chamfered or other formed transitions between adjoining surfaces (e.g., corners). Advantageously, the coating 130 allows the torsion spring 100 to withstand exposure to heat, acid, water, and other ionic species contained in the acidizing fluid while allowing for the torsion spring 100 to function in downhole applications such as operation of the subsurface safety valve 20.

In the illustrated embodiment, the torsion spring 100 includes the spring member 110 formed into a coil segment 120 and spring ends 140. In the illustrated embodiment, the coil segment 120 is formed from a plurality of coils 125 formed by coiling the spring metal forming the torsion spring 100. The coils 125 can be defined by the functional requirements of the torsion spring 100. In the illustrated embodiment, the spring ends 140 interact with fixed or moving portions of equipment, including, but not limited to the flapper and the body of the subsurface safety valve 20 as previously described.

In the illustrated embodiment, the spring member 110 is formed from a Ni-base, Co-base or Ni—Co base alloy. More particularly the Ni-base or Co-base alloy may include a NiCoCrMo alloy. Even more particularly, spring member 110 may be formed from a NiCoCrMo alloy including, in weight percent: about 33.0-41.0% Co, about 14.0-37.0% Ni, about 19.0-21.0% Cr and about 6.0-10.5% Mo. In an exemplary embodiment, spring member 110 may be formed from an alloy comprising, in weight percent, about 33.0% Co, about 33.0-37.0% Ni, about 19.0-21.0% Cr and about 9.0-10.5% Mo. This alloy may also include about 0.01% B, about 0.025% or less of C, about 1.0% or less of Fe, about 0.15% or less of Mn, about 0.015% or less of P, about 0.15% or less of Si, about 0.01% or less of S, and about 1.0% or less of Ti. This may include the alloy known commercially as MP35N (UNSR 30035). Alloy MP35N is a multiphase, quaternary, high-strength, ductile alloy having a strength of over 300 ksi. In another embodiment, spring member 110 may be formed from a NiCoCrMo alloy comprising, in weight percent: about 39.0-41.0% Co, about 14.0-16.0% Ni, about 19.0-21.0% Cr and about 6.0-8.0% Mo. This alloy may also include, in weight percent: about 0.1% or less of Be, about 0.15% or less of C, about 11.25-20.5% Fe, and about 1.5-2.5% Mn. This alloy may include an alloy known commercially as Elgiloy (UNS R30003).

In other embodiments, the spring member 110 is formed from any material providing suitable characteristics for the task in which the torsion spring 100 is employed, e.g., high strength and resiliency for use as a spring. In certain embodiments, materials can include alloys of cobalt, nickel, chromium, and molybdenum, such as those marketed under the trade names Conichrome®, Phynox, etc.

In the illustrated embodiment, while the material of the spring member 110 is resistant to corrosion, the coating 130 can provide a barrier to corrosion in highly corrosive environments, such as during and immediately after certain borehole acidizing operations. Advantageously, the use of the coating 130 can prevent corrosion and damage to the spring member 110. Further, as described herein, the application and composition of the coating 130 can prevent lack of adhesion or cracking of the coating on the torsion spring 100.

Referring to FIGS. 5A and 5B, the torsion spring 100 is shown with a coating 130 disposed around the outer surface 150 of the spring member 110. In FIG. 5A the spring member 100 is shown to have a circular cross-section, while in FIG. 5B, the spring member 100 is shown to have a rectangular cross-section. In the illustrated embodiment, the coating 130 is resistant to exposure from hydrochloric acid, hydrochloric acids with other chlorides, etc. In the illustrated embodiment, the coating 130 is formed from iridium. In certain embodiments, the coating 130 is formed from a platinum alloy. In certain embodiments, platinum can be alloyed with iridium or any other suitable metal to form the coating 130. In certain embodiments, a platinum-iridium alloy can include approximately 90% platinum and 10% iridium. In other embodiments, a platinum-iridium alloy can include 60% platinum and 40% iridium. In other embodiments, the platinum-iridium alloy can be any suitable composition. In other embodiments, the coating can be formed from any suitable metal or alloy, including, but not limited to other platinum-group metals or precious metals such as gold.

In the illustrated embodiment, various techniques can be utilized to apply the coating 130 to the spring member 110 to allow for proper adhesion of the coating without weakening or otherwise damaging the spring member 110. In the illustrated embodiment, the spring member 110 is generally formed to a desired form, such as the spring 100 shown in FIGS. 2 and 3. The spring member 110 can be formed to include ends 140 and a coil segment 120 with coils 125.

In certain embodiments, the spring member 110 can be age hardened or otherwise heat treated to increase the strength of the spring member 110. Further, in certain embodiments, the spring member 110 can be polished before the coating 130 is applied to facilitate inspection for flaws. In certain embodiments, the spring member 110 is electro polished, chemically cleaned or polished, inert gas plasma cleaning, or abrasively polished.

In the illustrated embodiment, the coating 130 can be applied to the outer surface 150 of the spring member 110 by plasma assisted physical vapor deposition. In the illustrated embodiment, plasma assisted physical vapor deposition is performed by placing the torsion spring 100 in a vacuum chamber suitable for plasma assisted physical vapor deposition. The chamber can be evacuated and filled with argon, or any other suitable inert gas. The torsion spring 100 can further be ion cleaned. In certain embodiments, an intermediate alloy layer can be deposited on the outer surface 150 of the spring member 110 before the coating 130 is applied. In certain embodiments, the intermediate alloy layer is a layer of Elgiloy or other suitable alloy. In certain applications, the use of an intermediate alloy layer can enhance adhesion of the coating 130 to the outer surface 150. The coating 130 is then applied to the outer surface 150. In the illustrated embodiment, platinum-group metals such as iridium can be vaporized and ionized to accelerate and deposit metallic ions on the outer surface 150 of the torsion spring 100. In certain embodiments, RF power is utilized to create and maintain plasma during the coating process. In the illustrated embodiment, the coating 130 is deposited until a desired thickness is achieved. In certain embodiments, the spring member 110 can further include a sacrificial coating in areas of high wear, including, but limited to tensile stressed spring surfaces. Further, in certain embodiments, sacrificial coatings can be applied to mating portions of the subsurface safety valve 20 or other components that may be in contact with the torsion spring 100. Sacrificial coatings include, but are not limited to, thin film bonded lubricant coatings, such as PTFE, or additional coating layers 130 as described herein.

In other embodiments, suitable deposition methods to apply the coating 130 include plating, diffusion, chemical vapor deposition or other forms of physical vapor deposition, or a combination thereof. Suitable plating methods to apply the coating 130 include ion plating and electrolytic plating. In certain embodiments, electrolytic plating can be utilized to deposit a platinum alloy as a coating 130 on the outer surface 150 of the torsion spring. In certain embodiments, a platinum alloy with 60% platinum and 40% iridium can be deposited on the outer surface 150 with an electrolytic plating process.

Advantageously, the application of the coating 130 provides for a barrier that adheres to the outer surface 150 of the spring member 110. The coating 130 can reduce propensity for environment assisted cracking by virtue of its enhanced acidizing fluid resistance.

Therefore, in one aspect, a spring is disclosed that in one non-limiting embodiment contains a spring member including a Ni-base, Co-base or Ni—Co base alloy, the spring member having an outer surface, and a coating disposed on the outer surface of the spring member, wherein the coating includes a metal. In certain embodiments, the metal is a platinum-group metal. In certain embodiments, the platinum-group metal is iridium. In certain embodiments, the coating is a platinum alloy. In certain embodiments, the platinum alloy is a platinum-iridium alloy. In certain embodiments, the coating is deposited via physical vapor deposition. In certain embodiments, the physical vapor deposition is plasma assisted physical vapor deposition. In certain embodiments, the spring member is age hardened. In certain embodiments, the spring member is chemically cleaned. In certain embodiments, the coating is deposited via electroplating.

In another aspect a method of making a spring is disclosed that in one non-limiting embodiment includes forming a spring member including a Ni-base, Co-base or Ni—Co base alloy, the spring member having an outer surface, and disposing a coating on the outer surface of the spring member, wherein the coating includes a metal. In certain embodiments, the metal is a platinum-group metal. In certain embodiments, the platinum-group metal is iridium. In certain embodiments, the coating is a platinum alloy. In certain embodiments, the platinum alloy is a platinum-iridium alloy. In certain embodiments, the method further includes depositing the coating on the outer surface of the spring member via physical vapor deposition.

In another aspect a subsurface safety valve is disclosed that in one non-limiting embodiment includes a valve body, a flapper rotatably coupled to the valve body, and a spring configured to rotatably urge the flapper against the valve body, wherein the spring includes a spring member including an Ni-base, Co-base or Ni—Co base alloy, the spring member having an outer surface, and a coating disposed on the outer surface of the spring member, wherein the coating includes a metal. In certain embodiments, the metal is a platinum-group metal. In certain embodiments, the platinum-group metal is iridium. In certain embodiments, the coating is a platinum alloy.

In another aspect downhole assembly disposed in a wellbore is disclosed that in one non-limiting embodiment includes a tubing disposed in the wellbore, a subsurface safety valve associated with the tubing, the subsurface safety valve including a valve body, a flapper rotatably coupled to the valve body, and a spring configured to rotatably urge the flapper against the valve body, wherein the spring includes a spring member including an Ni-base, Co-base or Ni—Co basealloy, the spring member having an outer surface, and a coating disposed on the outer surface of the spring member, wherein the coating includes a platinum-group metal.

1. A spring, comprising:
a spring member including an Ni-base, Co-base or Ni—Co base alloy, the spring member having an outer surface; and
a coating disposed on the outer surface of the spring member, wherein the coating includes a metal.

2. The spring of claim 1, wherein the metal is a platinum-group metal.

3. The spring of claim 2, wherein the platinum-group metal is iridium.

4. The spring of claim 1, wherein the coating is a platinum alloy.

5. The spring of claim 4, wherein the platinum alloy is a platinum-iridium alloy.

6. The spring of claim 1, wherein the coating is deposited via physical vapor deposition.

7. The spring of claim 6, wherein the physical vapor deposition is plasma assisted physical vapor deposition.

8. The spring of claim 1, wherein the spring member is age hardened.

9. The spring of claim 1, wherein the spring member is chemically cleaned.

10. The spring of claim 1, wherein the coating is deposited via electroplating.

11. A method of making a spring, comprising:
forming a spring member including an Ni-base, Co-base or Ni—Co base alloy, the spring member having an outer surface; and
disposing a coating on the outer surface of the spring member, wherein the coating includes a metal.

12. The method of claim 11, wherein the metal is a platinum-group metal.

13. The method of claim 12, wherein the platinum-group metal is iridium.

14. The method of claim 11, wherein the coating is a platinum alloy.

15. The method of claim 14, wherein the platinum alloy is a platinum-iridium alloy.

16. The method of claim 11, further comprising depositing the coating on the outer surface of the spring member via physical vapor deposition.

17. A subsurface safety valve, comprising:
a valve body;
a flapper rotatably coupled to the valve body; and
a spring configured to rotatably urge the flapper against the valve body, wherein the spring includes:
a spring member including an Ni-base, Co-base or Ni—Co base alloy, the spring member having an outer surface; and
a coating disposed on the outer surface of the spring member, wherein the coating includes a metal.

18. The subsurface safety valve of claim 17, wherein the metal is a platinum-group metal.

19. The subsurface safety valve of claim 18, wherein the platinum-group metal is iridium.

20. The subsurface safety valve of claim 17, wherein the coating is a platinum alloy.

21. A downhole assembly disposed in a wellbore, the downhole assembly comprising:
a tubing disposed in the wellbore;
a subsurface safety valve associated with the tubing, the subsurface safety valve including:
a valve body;
a flapper rotatably coupled to the valve body; and
a spring configured to rotatably urge the flapper against the valve body, wherein the spring includes:
a spring member including an Ni-base, Co-base or Ni—Co base alloy, the spring member having an outer surface; and
a coating disposed on the outer surface of the spring member, wherein the coating includes a metal.
